(19) United States
(12) Patent Application Publication
(10) Pub. No.: US 2015/0257268 A1
(43) Pub. Date: Sep. 10, 2015

(54) PRINTED WIRING BOARD AND METHOD FOR MANUFACTURING PRINTED WIRING BOARD

(71) Applicant: IBIDEN CO., LTD., Ogaki-shi (JP)

(72) Inventors: Katsutoshi KITAGAWA, Ogaki-shi (JP); Tomoya Sawamura, Ogaki-shi (JP)

(73) Assignee: IBIDEN CO., LTD., Ogaki-shi (JP)

(21) Appl. No.: 14/640,577

(22) Filed: Mar. 6, 2015

(30) Foreign Application Priority Data
Mar. 7, 2014 (JP) 2014-045348

(51) Int. Cl. H05K 1/11

(52) U.S. Cl. CPC H05K 1/115

(57) ABSTRACT

A printed wiring board includes a core substrate, and a buildup layer formed on the core substrate and including an interlayer resin insulation layer and a conductive layer. The core substrate includes a metal core, a first insulation layer on first surface of the metal core, a first conductive layer on the first insulation layer, a second insulation layer on second surface of the metal core, and a second conductive layer on the second insulation layer, the metal core has a penetrating hole penetrating from the first surface to the second surface and a resin portion filling the penetrating hole, the resin portion includes resin material from the first insulation layer, the core substrate has a through-hole conductor formed in the resin portion through the metal core, the interlayer resin insulation layer has a core material, and the first insulation layer does not have a core material.

### CROSS-REFERENCE TO RELATED APPLICATIONS

The present application is based upon and claims the benefit of priority to Japanese Patent Application No. 2014-045348, filed Mar. 7, 2014, the entire contents of which are incorporated herein by reference.

### BACKGROUND OF THE INVENTION

1. Field of the Invention

The present invention relates to a method for manufacturing a printed wiring board by using a support plate and by successively laminating buildup multilayers, and to a printed wiring board formed by such a method.

2. Description of Background Art

In JP2013-77699A, the insulation layer directly on the metal core has a double-layer structure with a low CTE material on the lower side and a high CTE material on the upper side. The entire contents of this publication are incorporated herein by reference.

### SUMMARY OF THE INVENTION

According to one aspect of the present invention, a printed wiring board includes a core substrate, and a buildup layer formed on the core substrate and including an interlayer resin insulation layer and a conductive layer. The core substrate includes a metal core, a first insulation layer formed on a first surface of the metal core, a first conductive layer formed on the first insulation layer, a second insulation layer formed on a second surface of the metal core, and a second conductive layer formed on the second insulation layer, the metal core has a penetrating hole penetrating from the first surface to the second surface and a resin portion filling the penetrating hole, the resin portion includes a resin material derived from the first insulation layer, the core substrate has a through-hole conductor formed in the resin portion through the metal core, the interlayer resin insulation layer in the buildup layer has a core material, and the first insulation layer in the core substrate does not have a core material.

According to another aspect of the present invention, a method for manufacturing a printed wiring board includes forming a core substrate including a metal core, a first insulation layer formed on a first surface of the metal core, a first conductive layer formed on the first insulation layer, a second insulation layer formed on a second surface of the metal core, and a second conductive layer formed on the second insulation layer, and forming on the core substrate a buildup layer including an interlayer resin insulation layer and a conductive layer. The forming of the core substrate includes forming the first insulation layer which does not have a core material, forming a penetrating hole in the metal core such that the metal core penetrates from the first surface to the second surface of the metal core, filling a resin material derived from the first insulation layer into the penetrating hole such that a resin portion filling the penetrating hole is formed, and forming a through-hole conductor in the resin portion through the metal core, and the forming of the buildup layer includes forming the interlayer resin insulation layer which has a core material.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A-1D show views of steps in a method for manufacturing a printed wiring board according to a first embodiment of the present invention;

FIG. 2A-2D show views of steps in the method for manufacturing a printed wiring board according to the first embodiment;

FIG. 3A-3D show views of steps in the method for manufacturing a printed wiring board according to the first embodiment;

FIG. 4A-4D show views of steps in the method for manufacturing a printed wiring board according to the first embodiment;

FIG. 5A-5D show views of steps in the method for manufacturing a printed wiring board according to the first embodiment;

FIG. 6A-6C show views of steps in the method for manufacturing a printed wiring board according to the first embodiment;

FIG. 7 shows a cross-sectional view of a printed wiring board according to the first embodiment; and

FIG. 8 shows a cross-sectional view of a printed wiring board according to a first modified example of the first embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

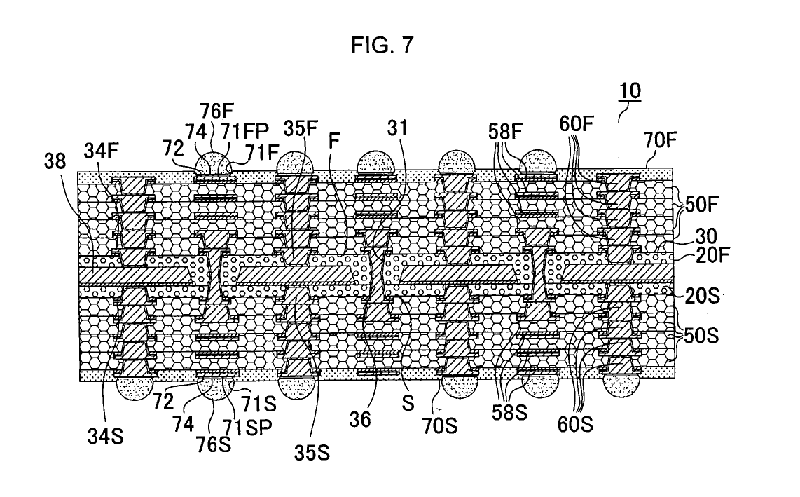

FIG. 7 shows a printed wiring board according to a first embodiment. Printed wiring board 10 has core substrate 30 formed with upper insulation layer (20F) and lower insulation layer (20S).

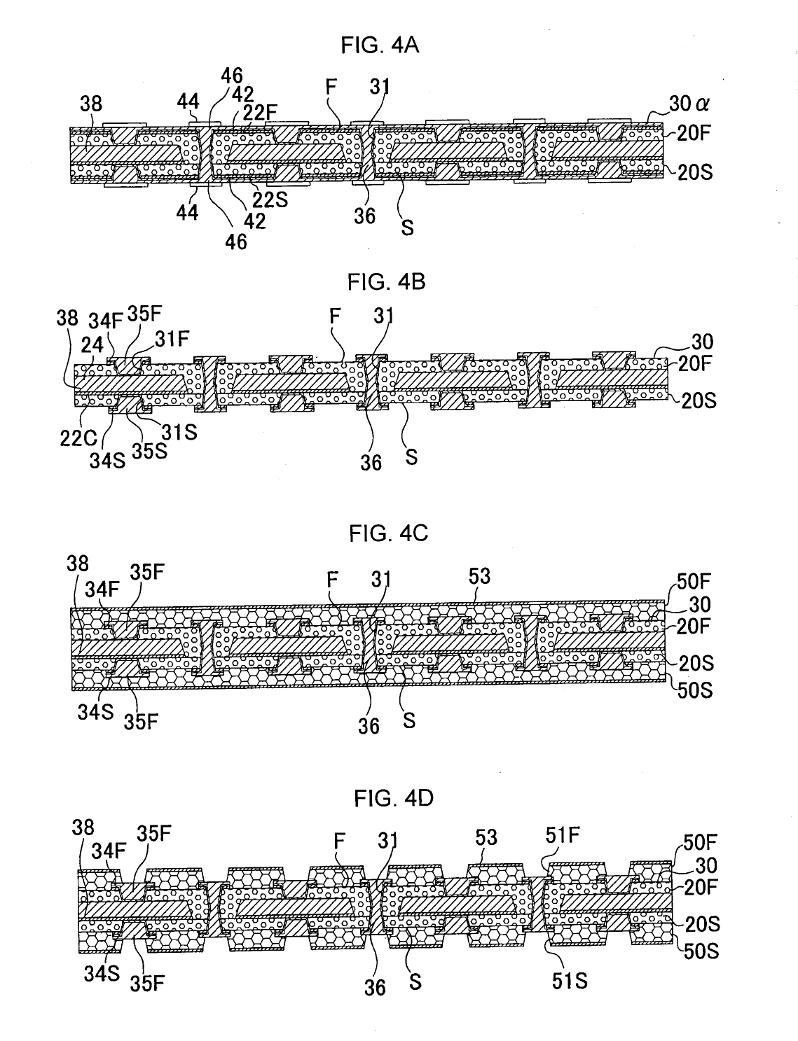

FIG. 4(B) shows core substrate 30. Upper conductive layer (34F) is formed on upper insulation layer (20F) and lower conductive layer (34S) is formed under lower insulation layer (20S). Metal core 38 is formed between the upper insulation layer and the lower insulation layer. Upper via conductor (35F) is formed in opening (31F) of upper insulation layer (20F) to connect upper conductive layer (34F) and metal core 38. Lower via conductor (35S) is formed in opening (31S) of lower insulation layer (20S) to connect lower conductive layer (34S) and metal core 38. Metal core 38 is formed by patterning core metal foil (22C) and electrolytic plated film 24 formed on core metal foil (22C). The thickness of metal core 38 is preferred to be 100˜200 μm. With such a thickness, the strength of a printed wiring board is enhanced, and heat radiation capability is improved. If the thickness is less than 100 μm, heat radiation capability is not improved. If the thickness exceeds 200 μm, there will be a higher risk of voids remaining in a penetrating hole even if the upper insulation layer is a resin layer that does not contain core material. Upper via conductor (35F) is formed to taper with a diameter decreasing downward, and lower via conductor (35S) is formed to taper with a diameter decreasing upward.

As shown in FIG. 7, in a printed wiring board of the first embodiment, four layers of first insulation layers (50F) each having first conductive layer (58F) and first via conductor (60F) are successively built up on first surface (F) of core substrate 30, while four layers of second insulation layers (50S) each having second conductive layer (58S) and second via conductor (60S) are successively built up on second surface (S) of core substrate 30. Solder-resist layer (70F) is formed on the uppermost first insulation layer (50F), and solder bump (76F) is formed in opening (71F) of solder-resist layer (70F). Solder-resist layer (70S) is formed on the lowermost second insulation layer (50S), and solder bump (76S) is formed in opening (71S) of solder-resist layer (70S).

Printed wiring board 10 of the first embodiment has a metal core structure having metal core 38 in the center of core substrate 30. Thus, because of the rigidity of thick metal core 38, warping is suppressed, and demand for thinner boards is satisfied. In addition, thermal conductivity of the printed wiring board is improved by metal core 38.

### Manufacturing Method of First Embodiment

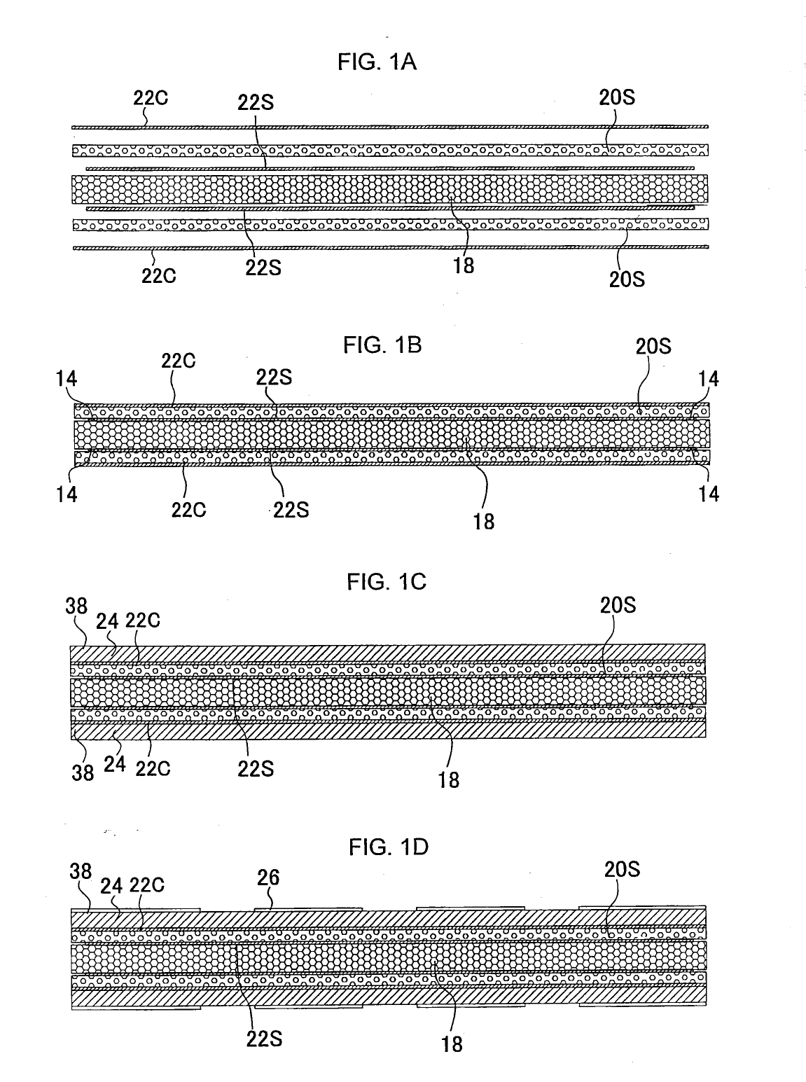

A method for manufacturing printed wiring board 10 of the first embodiment is shown with reference to FIG. 1˜6.

(1) Support plate 18 is prepared. Support plate 18 is, for example, a copper-clad laminate (double-sided copper-clad laminate) made of an insulative base and copper foil (not shown) laminated on both surfaces of the insulative base. The support plate has a first surface and a second surface opposite the first surface. Lower metal foil (22S) is provided on the first and second surfaces of support plate 18. Metal foil (22S) is a copper foil, for example, and has a thickness of 12 μm. B-stage resin film 22 is provided to be placed on lower metal foil (22S), and core metal foil (22C) is provided to be placed on resin film 22 (FIG. 1(A)). The thickness of resin film 22 is 40˜60 μm and the thickness of core metal foil (22C) is 12 μm. Lower metal foil (22S) is laminated on the first and second surfaces of support plate 18. Support plate 18 and metal foil (22S) are fixed on their peripheries. The copper-clad laminate and metal foil are bonded by using ultrasonic waves. The metal foil and the support plate are bonded at fixed portion 14. The width of the fixed portion is 30 mm from the edge of the substrate. The fixed portion is in a frame shape. B-stage resin film is laminated on lower metal foil (22S), and core metal foil (22C) is laminated thereon (FIG. 1B). Then, the resin film is cured to form lower insulation layer (20S) on the support plate. Lower insulation layer (20S) contains inorganic particles but does not include core material. Examples of inorganic particles are those made of silica, alumina and hydroxides. Examples of hydroxides are metal hydroxides such as aluminum hydroxide, magnesium hydroxide, calcium hydroxide, and barium hydroxide. Hydroxides are decomposed by heat to produce water. As a result, hydroxides are thought to rob heat of the material forming insulation layers. Namely, when lower insulation layer (20S) contains a hydroxide, laser processability is thought to be enhanced.

(2) On 12 μm-thick core metal foil (22C), 88˜188 μM (preferably 100 μm) thick electrolytic plated film 24 is formed. Accordingly, 100˜200 μm thick metal core 38 made up of metal foil (22C) and electrolytic plated film 24 is formed (FIG. 1(C)).

(3) Etching resist 26 with a predetermined pattern is formed on electrolytic plated film 24 (FIG. 1(D)).

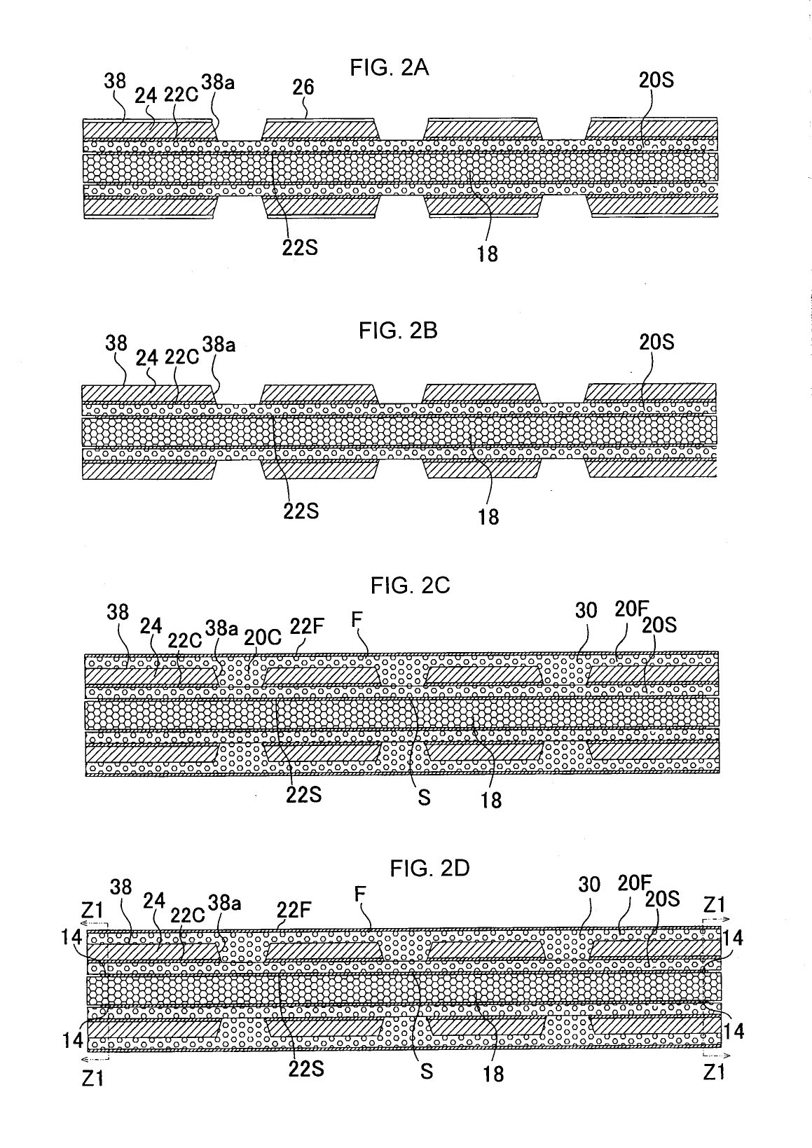

(4) Electrolytic plated film 24 and core metal foil (22C) where no etching resist is formed are etched away to form penetrating hole (38a) (FIG. 2(A)). Then, the etching resist is removed and metal core 38 made of electrolytic plated film 24 and core metal foil (22C) is formed (FIG. 2(B)). Penetrating hole (38a) tapers from the upper surface toward the lower surface of the metal core.

(5) On the first surface of the lower insulation layer and on metal core 38, upper insulation layer (20F) and upper metal foil (22F) are formed (FIG. 2(C)). The upper insulation layer contains inorganic particles the same as those in the lower insulation layer, but does not contain core material, and has a thickness of 40˜60 μm. Upper metal foil (22F) is made of copper foil, for example, the same as the lower metal foil, and has a thickness of 12 μm. When upper insulation layer (20F) is laminated, penetrating hole (38a) of the metal core is filled with resin (20C) that has seeped from upper insulation layer (20F). Here, the thickness of the upper insulation layer is preferred to be set thicker in advance than that of the lower insulation layer so that their final thicknesses will be the same.

In the method for manufacturing a printed wiring board of the present embodiment, upper insulation layer (20F) that fills penetrating hole (38a) of the metal core with its resin does not contain core material. Thus, unlike insulation layers with core material, resin seeps out more easily, and resin (20C) is filled in penetrating hole (38a) without causing voids. Since hardly any voids are formed in the core substrate, the printed wiring board has high reliability. Also, since penetrating hole (38a) tapers from the upper surface toward the lower surface, resin from the upper insulation layer (20F) on the upper surface side is more likely to be filled, and voids are less likely to occur in penetrating hole (38a).

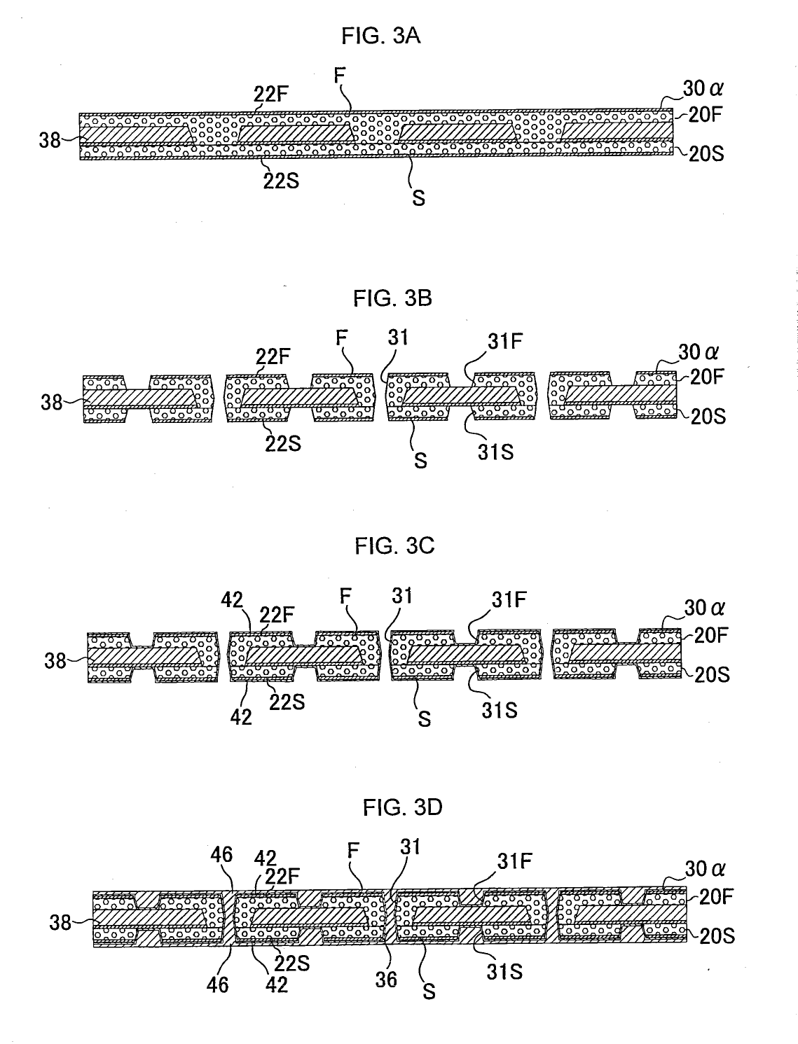

(6) The intermediate bodies with the support plate are cut along the (Z1-Z1) lines in FIG. 2(D). The cutting portion is inside fixed portion 14. Intermediate body (30a) is separated from support plate 18 (FIG. 3(A)).

(7) Laser is irradiated on upper insulation layer (20F). Upper opening (31F) is formed in the upper insulation layer to reach metal core 38. Laser is irradiated on lower insulation layer (20S). Lower opening (31S) is formed in the lower insulation layer to reach metal core 38. In addition, laser is irradiated on upper insulation layer (20F) and lower insulation layer (20S) to form penetrating hole 31 for a through-hole conductor (FIG. 3(B)). Upper opening (31F) tapers from the surface of the upper insulation layer toward metal core 38. Lower opening (31S) tapers from the surface of the lower insulation layer toward metal core 38. Penetrating hole 31 for a through-hole conductor is formed in an hourglass shape, tapering from the surface of the upper insulation layer while tapering from the surface of the lower insulation layer.

(8) Electroless plated film 42 is formed on upper and lower metal foils (22F, 22S), and on the inner walls of upper and lower openings (31F, 31S) and of penetrating hole 31 for a through-hole conductor (FIG. 3(C)).

(9) Using the electroless plated film as a seed layer, electrolytic plated film 46 is formed on electroless plated film 42. Upper opening (31F) and lower opening (31S) are filled with electrolytic plated film 46, and electrolytic plated film 46 is formed on electroless plated film 42 positioned on upper metal foil (22F) and lower metal foil (22S) (FIG. 3(D)).

(10) Etching resist 44 with a predetermined pattern is formed on electrolytic plated film 46 positioned on the first-surface (F) side and second-surface (S) side (FIG. 4(A)).

(11) Electrolytic plated film 46, electroless plated film 42 and upper metal foil (22F) on the first-surface (F) side where no etching resist is formed, as well as electrolytic plated film 46, electroless plated film 42 and lower metal foil (22S) on the second-surface (S) side where no etching resist is formed, are removed by etching. Then, the etching resist is removed. Accordingly, core substrate 30 is provided with upper conductive layer (34F) made of electrolytic plated film 46, electroless plated film 42 and upper metal foil (22F) on the first-surface (F) side, as well as conductive layer (34S) made of electrolytic plated film 46, electroless plated film 42 and lower metal foil on the second-surface (S) side (22S) (FIG. 4(B)). The thicknesses of upper conductive layer (34F) and lower conductive layer (34S) are each 20 μm.

(12) First insulation layer (50F) and metal foil 53 are formed on first surface (F), and second insulation layer (50S) and metal foil 53 are formed on second surface (S) of core substrate 30 (FIG. 4(C)). First insulation layer (50F) and second insulation layer (50S) each have a thickness of 40 μm˜60 μm. The thickness of metal foil 53 is 12 μm. First insulation layer (50F) is formed on the first surface of the upper insulation layer and on upper conductive layer (34F). Second insulation layer (50S) is formed on the second surface of the lower insulation layer and on lower conductive layer (34S). The thicknesses of the insulation layers are each 40 μm˜60 μm. Metal foil 53 is copper foil, for example, the same as the upper and lower metal foils, and has a thickness of 12 μm. First and second insulation layers contain inorganic particles and reinforcement material. As for reinforcement material, glass cloth, aramid fiber, glass fiber or the like may be used. Glass cloth is preferred. First and second insulation layers are preferred to have the same thickness as upper and lower insulation layers.

(13) Next, using a CO2 gas laser, first via-conductor opening (51F) and second via-conductor opening (51S) are respectively formed in first insulation layer (50F) and second insulation layer (50S) (FIG. 4(D)).

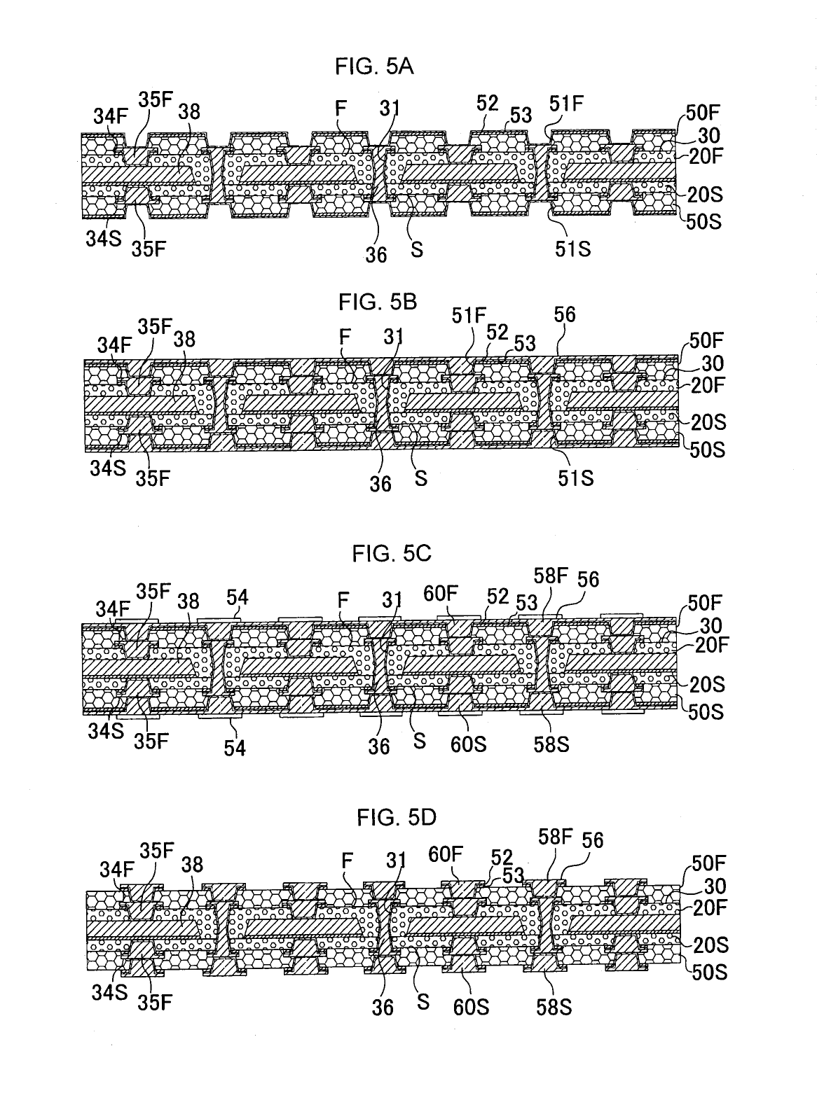

(14) Electroless plated film 52 is formed on first insulation layer (50F) and second insulation layer (50S), and in first opening (51F) and second opening (51S) (FIG. 5(A)).

(15) Using the electroless plated film as a seed layer, electrolytic plated film 56 is formed on electroless plated film 52. First opening (51F) and second opening (51S) are filled with electrolytic plated film 56, and electrolytic plated film 56 is formed on electroless plated film 52 positioned on metal foil 53 (FIG. 5(B)).

(16) Etching resist 54 with a predetermined pattern is formed on electrolytic plated film 56 (FIG. 5(C)).

(17) Electrolytic plated film 56, electroless plated film 52 and metal foil 53 where no etching resist is formed are removed by etching, and the etching resist is removed. Accordingly, first via conductor (60F) is formed in first opening (51F), second via conductor (60S) is formed in second opening (51S), first conductive layer (58F) made of electrolytic plated film 56, electroless plated film 52 and metal foil 53 is formed on the first surface of the first insulation layer, while second conductive layer (58S) made of electrolytic plated film 56, electroless plated film 52 and metal foil 53 is formed on the second surface of the second insulation layer (FIG. 5(D)).

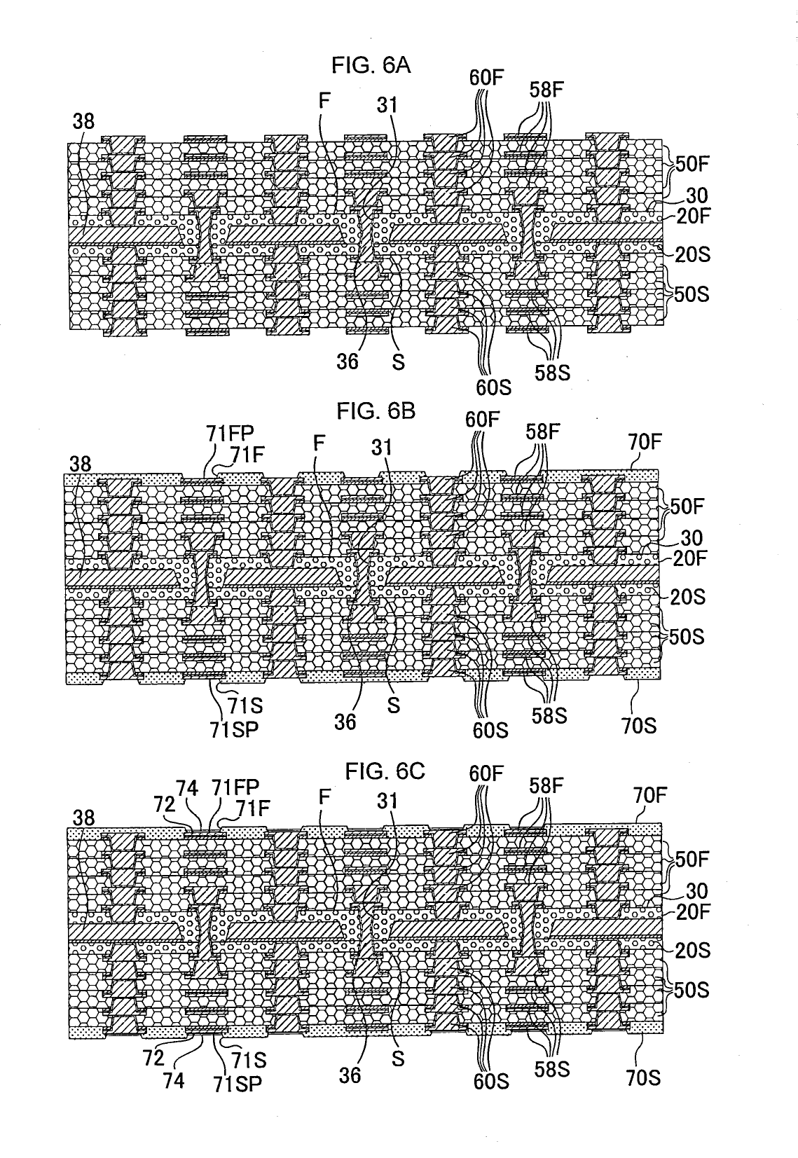

(18) Procedures described with reference to FIG. 4(C)˜5(D) are repeated so that three layers of first insulation layers (50F) each having first conductive layer (58F) and first via conductor (60F), along with three layers of second insulation layers (50S) each having second conductive layer (58S) and second via conductor (60S), are further built up (FIG. 6(A)).

(19) Upper solder-resist layer (70F) having opening (71F) is formed on uppermost first insulation layer (50F), and lower solder-resist layer (70S) having opening (71S) is formed on lowermost second insulation layer (505) (FIG. 6(B)). Upper surfaces of conductive layers (58F, 58S) and via conductors (60F, 60S) that are exposed respectively from openings (71F, 71S) work as pads (71FP, 71SP).

(20) Nickel-plated layer 72 is formed on pads (71 FP, 71 SP) and gold-plated layer 74 is further formed on nickel-plated layer 72 (FIG. 6(C)).

(21) Solder paste is printed in openings (71F, 71S), and reflow is conducted. Accordingly, solder bump (76F) is formed on the upper buildup layer, and solder bump (76S) is formed on the lower buildup layer. Printed wiring board 10 is completed (FIG. 7).

In the method for manufacturing a printed wiring board according to the first embodiment, an intermediate body is formed on support plate 18. Even if each insulation layer is thin, cracking or breakage caused by transfer or the like seldom occurs in insulation layers or conductive layers of the intermediate body. In addition, since the intermediate body includes two insulation layers (20F, 20S) and one thick metal core 38, its strength is high. Therefore, even after the intermediate body is separated from the support plate, the degree of warping or undulation is small in the intermediate body. Thus, when the intermediate body undergoes transfer or further process without the support plate, it is less likely to be damaged. Production yield of core substrates and printed wiring boards increases and connection reliability is enhanced. Also, thin printed wiring boards can be manufactured efficiently. In the manufacturing method for the first embodiment, buildup layers are formed without using jigs. Fine conductive circuits are formed.

The method for manufacturing a printed wiring board according to the first embodiment employs a metal core structure, providing metal core 38 in the center of core substrate 30. Thus, warping is suppressed due to the rigidity of metal core 38, and the demand for thinner boards is satisfied. Also, since a core substrate is separated from support plate 18 after it is formed on the support plate, the core substrate with a metal core structure is manufactured by a simplified manufacturing process. The manufacturing cost is reduced and yield is improved.

Core material such as glass cloth has a higher thermal conductivity, and insulation layers (first and second insulation layers) with core material have a thermal conductivity of 0.62 W/mk. By contrast, insulation layers without core material have a thermal conductivity of 0.19 W/mk. In the printed wiring board of the first embodiment, four layers of first insulation layers (50F) containing core material are built up on first surface (F) of core substrate 30, and four layers of second insulation layers (50S) containing core material are built up on second surface (S) of core substrate 30. Accordingly, heat radiation is enhanced through those buildup layers.

### First Modified Example of First Embodiment

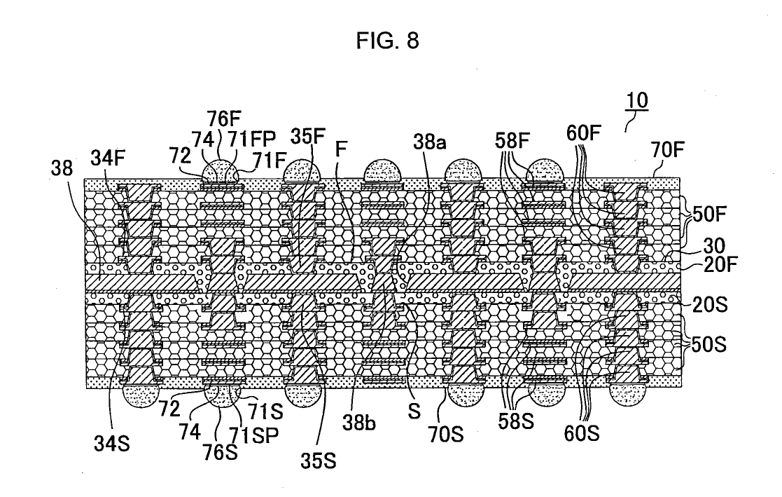

FIG. 8 shows a printed wiring board according to a modified example of the first embodiment. Printed wiring board 10 contains core substrate 30 which has upper insulation layer (20F) and lower insulation layer (20S). In the modified example, metal core piece (38b) is formed, being insulated by resin filled in penetrating hole (38a) of metal core 38. Via conductor (35F) formed in upper insulation layer (20F) and via conductor (35S) formed in lower insulation layer (20S) are connected to metal core piece (38b), and first insulation layer (50F) and second insulation layer (50S) are joined.

### Reference Example

A printed wiring board as a reference example is manufactured by omitting the metal core from the structure of a printed wiring board according to the first embodiment. A processor was mounted on a printed wiring board of the reference example, and the maximum temperature of the processor was measured. As a result, the temperature of the processor rose to 113.6° C. By contrast, when the same processor was mounted on a printed wiring board of the first embodiment and its maximum temperature was measured, the temperature of the processor rose only to 97.5° C. Namely, a printed wiring board with a built-in metal core according to the first embodiment exhibited an effect of a 14% reduction in maximum temperature.

As electronic devices become thinner, built-in printed wiring boards are required to be thinner. When a printed wiring board is made thinner, the rigidity of insulation layers decreases and warping or the like tends to occur. To deal with such problems, various structures using a highly rigid metal plate may be used inside a core substrate for a multilayer buildup printed wiring board with buildup layers formed on a core substrate.

To form a metal-core printed wiring board, it is hard to avoid voids when resin is filled in a penetrating hole in the metal core for forming a through-hole conductor. Problems arise as cracks originating in voids in the penetrating hole tend to occur in insulation layers.

A printed wiring board according to an embodiment of the present invention is highly reliable, and another embodiment of the present invention is a method for manufacturing such a printed wiring board.

A printed wiring board according to one aspect of the present invention has a core substrate formed with the following: a metal core having a penetrating hole and upper and lower surfaces; an upper insulation layer and an upper conductive layer formed on the upper surface of the metal core; a lower insulation layer and a lower conductive layer formed on the lower surface of the metal core; resin that has seeped from the upper insulation layer and has filled in the penetrating hole in the metal core; a through-hole conductor formed in the resin; an upper via conductor formed in the upper insulation layer and connecting the metal core and the upper conductive layer; and a lower via conductor formed in the lower insulation layer and connecting the metal core and the lower conductive layer. On the core substrate, the printed wiring board also has a buildup layer made up of interlayer resin insulation layers and conductive layers. The interlayer resin insulation layers contain core material, but the upper insulation layer does not contain core material.

A method for manufacturing a printed wiring board according to another aspect of the present invention includes the following: preparing a support plate; forming a core substrate on the support plate by successively laminating a lower insulation layer, a metal core having a penetrating hole, and an upper insulation layer, while filling the penetrating hole with the resin that has seeped from the upper insulation layer; removing the core substrate from the support plate; and forming a buildup layer by laminating interlayer resin insulation layers and conductive layers on the core substrate. The upper insulation layer does not contain core material, while the interlayer resin insulation layers contain core material.

In a printed wiring board according to an embodiment of the present invention, the upper insulation layer from which resin seeps to fill a penetrating hole in the metal core does not contain core material. Thus, unlike the insulation layer containing core material, resin seeps out more easily, and the penetrating hole is more likely to be filled with resin without resulting in voids. Since there are hardly any voids in the core substrate, the printed wiring board has higher reliability.

In a method for manufacturing a printed wiring board according to an embodiment of the present invention, the upper insulation layer from which resin seeps to fill a penetrating hole in the metal core does not contain core material. Thus, unlike the insulation layer containing core material, resin seeps out more easily, and the penetrating hole is more likely to be filled with resin without resulting in voids. Since there are hardly any voids in the core substrate, the printed wiring board has higher reliability.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a core substrate; and
a buildup layer formed on the core substrate and comprising an interlayer resin insulation layer and a conductive layer,
wherein the core substrate includes a metal core, a first insulation layer formed on a first surface of the metal core, a first conductive layer formed on the first insulation layer, a second insulation layer formed on a second surface of the metal core, and a second conductive layer formed on the second insulation layer, the metal core has a penetrating hole penetrating from the first surface to the second surface and a resin portion filling the penetrating hole, the resin portion comprises a resin material derived from the first insulation layer, the core substrate has a through-hole conductor formed in the resin portion through the metal core, the interlayer resin insulation layer in the buildup layer has a core material, and the first insulation layer in the core substrate does not have a core material.

2. A printed wiring board according to claim 1, wherein the core substrate includes a first via conductor connecting the first conductive layer and the metal core, and a second via conductor connecting the second conductive layer and the metal core.

3. A printed wiring board according to claim 1, wherein the through-hole conductor is formed through the penetrating hole such that the through-hole conductor is connecting the first conductive layer and the second conductive layer.

4. A printed wiring board according to claim 2, wherein the through-hole conductor is formed through the penetrating hole such that the through-hole conductor is connecting the first conductive layer and the second conductive layer.

5. A printed wiring board according to claim 1, wherein the second insulation layer is formed such that the second insulation layer is closing an opening of the penetrating hole on the second surface of the metal core.

6. A printed wiring board according to claim 2, wherein the second insulation layer is formed such that the second insulation layer is closing an opening of the penetrating hole on the second surface of the metal core.

7. A printed wiring board according to claim 1, wherein the second insulation layer does not have a core material.

8. A printed wiring board according to claim 2, wherein the second insulation layer does not have a core material.

9. A printed wiring board according to claim 1, wherein the penetrating hole is formed such that the penetrating hole is tapering from the first surface toward the second surface of the metal core.

10. A printed wiring board according to claim 2, wherein the penetrating hole is formed such that the penetrating hole is tapering from the first surface toward the second surface of the metal core.

11. A printed wiring board according to claim 1, wherein the metal core has a thickness in a range of 100 μm to 200 μm.

12. A printed wiring board according to claim 2, wherein the metal core has a thickness in a range of 100 μm to 200 μm.

13. A printed wiring board according to claim 1, wherein the metal core comprises a metal foil and a copper plated layer formed on the metal foil.

14. A printed wiring board according to claim 2, wherein the metal core comprises a metal foil and a copper plated layer formed on the metal foil.

15. A printed wiring board according to claim 1, wherein the buildup layer comprising a plurality of the interlayer resin insulation layer and a plurality of the conductive layer.

16. A method for manufacturing a printed wiring board, comprising:
forming a core substrate comprising a metal core, a first insulation layer formed on a first surface of the metal core, a first conductive layer formed on the first insulation layer, a second insulation layer formed on a second surface of the metal core, and a second conductive layer formed on the second insulation layer; and
forming on the core substrate a buildup layer comprising an interlayer resin insulation layer and a conductive layer,
wherein the forming of the core substrate includes forming the first insulation layer which does not have a core material, forming a penetrating hole in the metal core such that the penetrating hole penetrates from the first surface to the second surface of the metal core, filling a resin material derived from the first insulation layer into the penetrating hole such that a resin portion filling the penetrating hole is formed, and forming a through-hole conductor in the resin portion through the metal core, and the forming of the buildup layer includes forming the interlayer resin insulation layer which has a core material.

17. A method for manufacturing a printed wiring board according to claim 16, wherein the forming of the core substrate includes laminating the metal core on the second insulation layer, and laminating the first insulation layer on the metal core having the penetrating hole such that the resin material of the first insulation layer fills the penetrating hole.

18. A method for manufacturing a printed wiring board according to claim 17, wherein the forming of the core substrate includes forming the core substrate on a support plate and removing the core substrate from the support plate.

19. A method for manufacturing a printed wiring board according to claim 16, wherein the forming of the core substrate includes forming a first via conductor in the first insulation layer such that the first via conductor connects the first conductive layer and the metal core, and forming a second via conductor in the second insulation layer such that the second via conductor connects the second conductive layer and the metal core.

20. A method for manufacturing a printed wiring board according to claim 16, wherein the forming of the penetrating hole includes forming the penetrating hole which is tapering from the first surface toward the second surface of the metal core.
